(19) United States
(12) Patent Application Publication
(10) Pub. No.: US 2026/0101535 A1
(43) Pub. Date: Apr. 9, 2026

(54) FORMING PLACEHOLDER FOR BACKSIDE CONTACT

(71) Applicant: International Business Machines Corporation, Armonk, NY (US)

(72) Inventors: Lijuan Zou, Albany, NY (US); Ruilong Xie, Niskayuna, NY (US); Tao Li, Slingerlands, NY (US); Fabio Carta, Pleasantville, NY (US); Erik Milosevic, Schenectady, NY (US)

(21) Appl. No.: 18/910,299

(22) Filed: Oct. 9, 2024

(51) Int. Cl. H01L 29/417; H01L 21/283; H01L 29/06; H01L 29/10; H01L 29/423; H01L 29/66; H01L 29/775; H01L 29/786

(52) U.S. Cl. CPC H10D 30/6729; H10D 62/116; H10D 62/235; H10P 14/40; H10D 30/014; H10D 30/43; H10D 30/6735; H10D 30/6757; H10D 62/121

(57) ABSTRACT

Embodiments of present invention provide a semiconductor structure. The semiconductor structure includes a transistor having a first and a second source/drain region; a backside contact in contact with a bottom surface of the first source/drain region; and a placeholder underneath the second source/drain region, where the placeholder is embedded in a backside interlevel-dielectric layer and includes a first and a second material that are different from each other and different from a material of the backside interlevel-dielectric layer. A method of forming the same is also provided.

### BACKGROUND

The present application relates to manufacturing of semiconductor integrated circuits. More particularly, it relates to forming placeholder for backside contact of transistor and the structure formed thereby.

As semiconductor industry moves towards smaller node, field-effect-transistors (FETs) are aggressively scaled to fit into reduced footprint or real estate with increased device density. In the meantime, some contacts to the transistors may be moved from the frontside to the backside of the transistors as well, known as backside contacts, as a mean to further enhance device density.

Generally, in order to form backside contacts, placeholders are usually first formed in the substrate during the frontside processing. The placeholders are then accessed from the backside of the substrate or device and replaced with backside contacts. In forming the placeholders, recesses are first formed in source/drain regions of transistors and openings are then made, through the recesses, in the substrate below the source/drain regions. However, with the ever shrinking gate-pitch such as when gate-pitch becomes less than 48 nm, the process of forming placeholders may be interfered or affected by other frontside processes. For example, openings created for the placeholders may be affected by pinch-off of liners.

### SUMMARY

Embodiments of present invention provide a semiconductor structure. The semiconductor structure includes a transistor having a first and a second source/drain (S/D) region; a backside contact in contact with a bottom surface of the first S/D region; and a placeholder underneath the second S/D region, where the placeholder is embedded in a backside interlevel-dielectric (BILD) layer and includes a first and a second material that are different from each other and different from a material of the BILD layer.

In one embodiment, the placeholder includes a first portion and a second portion over the first portion, the first portion being made of silicon-nitride and the second portion being made of epitaxial silicon-germanium, and wherein the BILD layer is made of silicon-oxide.

In another embodiment, the placeholder has an inverted trapezoidal shape with a wider base at top and a narrower base at bottom.

In one embodiment, the placeholder is made of epitaxial silicon-germanium and includes a first portion and a second portion over the first portion, the second portion being surrounded by a liner of silicon-nitride, and wherein the BILD layer is made of silicon-oxide.

In another embodiment, the first portion of the placeholder has a diamond shape and the second portion of the placeholder has an inverted trapezoidal shape with a wider base at top and a narrower base at bottom.

In yet another embodiment, the transistor is a nanosheet transistor having a plurality of nanosheets, and wherein a central portion of the plurality of nanosheets is surrounded by a metal gate of the transistor, the central portion of the plurality of nanosheets has a thickness that is less than a thickness of end portions of the plurality of nanosheets.

According to another embodiment, the semiconductor structure further includes an additional nanosheet underneath the plurality of nanosheets, the additional nanosheet being truncated by the metal gate.

According to another embodiment, the semiconductor structure further includes a frontside contact in contact with a top surface of the second S/D region.

Embodiments of present invention also provide a method of forming a semiconductor structure. The method includes forming a recess for a source/drain (S/D) region of a transistor on a substrate; forming a liner covering sidewalls of the recess; creating an opening below the recess in the substrate; forming a placeholder by filling the opening with a first material; forming the S/D region in the recess above the first placeholder; removing the placeholder from a backside of the substrate to expose a bottom surface of the S/D region; and forming a backside contact contacting the bottom surface of the S/D region.

In one embodiment, forming the placeholder further includes filling a portion of the recess above the opening with the first material, wherein the portion of recess is surrounded by the liner, and the liner is made of a second material different from the first material.

According to one embodiment, the method further includes trimming a set of nanosheets and wrapping around one or more trimmed nanosheets with a gate metal to form a metal gate of the transistor, wherein the set of nanosheets have a bottom-most nanosheet with a thickness that is thinner than rest of the set of nanosheets, and wherein trimming the set of nanosheets comprises truncating the bottom-most nanosheet.

In one embodiment, creating the opening includes selectively removing a sacrificial layer in the substrate to expose an embedded stub of a second material, and wherein forming the placeholder comprises depositing the first material on top of the embedded stub to fill the opening.

According to one embodiment, the method further includes creating a cavity in the substrate below the recess and filling the cavity with the second material to form the embedded stub at a lower portion of the cavity.

According to another embodiment, the method further includes forming the sacrificial layer in the cavity above the embedded stub before forming the liner to cover sidewalls of the recess in the S/D region.

According to yet another embodiment, the method further includes selectively removing the substrate and replacing with a layer of a third material, the third material being different from the first and the second material and surrounding the placeholder.

Embodiments of present invention provide a semiconductor structure. The structure includes a transistor having a first and a second source/drain region; a backside contact in contact with a bottom surface of the first S/D region; and a placeholder underneath the second S/D region, where the placeholder is embedded in a backside interlevel-dielectric layer and includes a first portion and a second portion of a first and a second material, the first and the second material are different from each other and different from a material of the BILD layer.

### BRIEF DESCRIPTION OF THE DRAWINGS

The present invention will be understood and appreciated more fully from the following detailed description of embodiments of present invention, taken in conjunction with accompanying drawings of which:

FIG. 1 to FIG. 15 are demonstrative illustrations of cross-sectional view of a semiconductor structure at various steps of manufacturing thereof according to one embodiment of present invention;

FIG. 16 to FIG. 31 are demonstrative illustrations of cross-sectional view of a semiconductor structure at various steps of manufacturing thereof according to another embodiment of present invention; and

FIG. 32 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

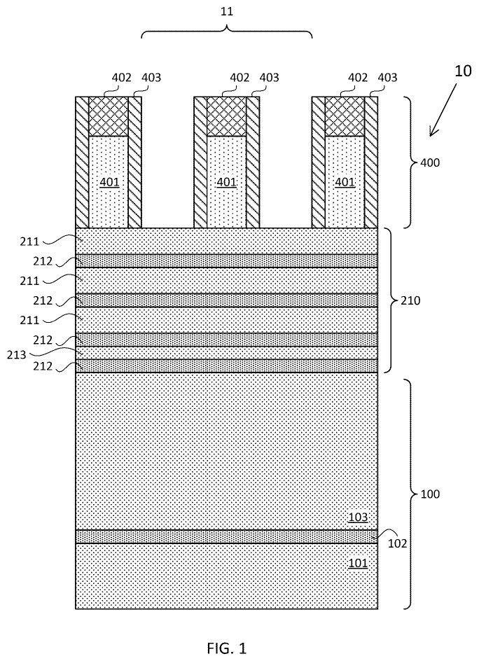

FIG. 1 is a demonstrative illustration of cross-sectional view of a semiconductor structure 10 in a step of manufacturing thereof according to one embodiment of present invention. As a non-limiting example, the semiconductor structure 10 may include a transistor such as a nanosheet (NS) transistor 11. FIG. 1 demonstratively illustrates a cross-sectional view of the NS transistor 11, at a step of manufacturing thereof, with a cross-section made along the length of gate of the NS transistor 11.

Embodiments of present invention provide receiving or providing a semiconductor substrate 100 and forming a stack of nanosheets 210 on top of the semiconductor substrate 100. The semiconductor substrate 100 may be a bulk silicon (Si) substrate, a bulk germanium (Ge) substrate, a silicon-germanium (SiGe) substrate, a silicon-on-insulator (SOI) substrate, a silicon-germanium-on-insulator (SGOI) substrate, and/or other suitable substrate. As is illustrated in FIG. 1, the semiconductor substrate 100 may be a SOI substrate that includes a bulk Si substrate 101, a dielectric layer 102 on top of the bulk Si substrate 101, and a Si layer 103 on top of the dielectric layer 102. During a subsequent process, the dielectric layer 102 may work or function as an etch-stop layer (ESL) and thus may be referred to as an ESL.

The stack of nanosheets 210 may include a bottom-most Si nanosheet 213 and a set of Si nanosheets 211 stacked on top thereof. The set of Si nanosheets 211 may be stacked together, alternately, with a set of sacrificial layers 212. In one embodiment, the bottom-most Si nanosheet 213 and the set of sacrificial layers 212 may have thicknesses that are thinner than thicknesses of the Si nanosheets 211. For example, when being compared with a set of conventional sacrificial layers in forming NS transistors, the thicknesses of the sacrificial layers 212 may be thinner or smaller. On the other hand, when being compared with a set of conventional Si nanosheets in forming NS transistors, the thicknesses of the Si nanosheets 211 may be thicker or bigger. The set of sacrificial layers 212 may be a set of SiGe layers, which may have an etch selectivity that is different from the set of Si nanosheets 211 and the Si nanosheet 213.

Embodiments of present invention further provide forming a set of sacrificial gate structures 400 on top of the stack of nanosheets 210. Each of the sacrificial gate structures 400 may include a sacrificial gate 401, a capping layer 402 on top of the sacrificial gate 401, and sidewall spacers 403 at sidewalls of the sacrificial gate 401 and the capping layer 402. The sacrificial gate 401 may include, for example, polysilicon (Poly-Si) in material, the capping layer 402 and sidewall spacers 403 may include dielectric material such as, for example, silicon-nitride (SiN), silicon-oxide (SiOx), or other suitable materials.

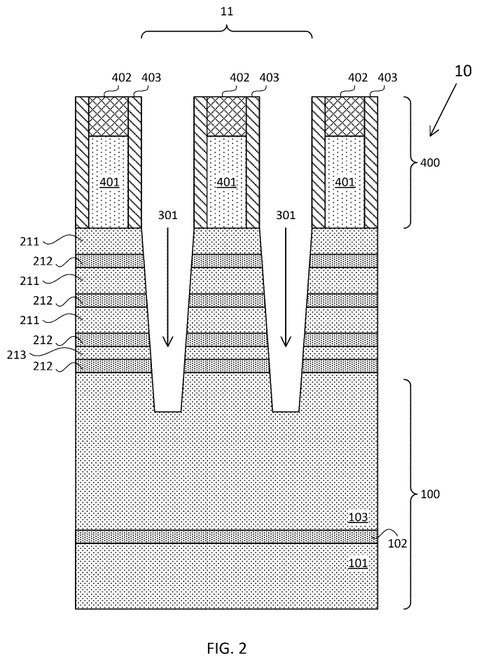

FIG. 2 is a demonstrative illustration of cross-sectional view of a semiconductor structure 10 in a step of manufacturing thereof, following the step illustrated in FIG. 1, according to one embodiment of present invention. More particularly, embodiments of present invention provide recessing the stack of nanosheets 210 in source/drain regions of the NS transistor 11, in a selective etch process using the sacrificial gate structures 400 as an etch mask. The recessing may create recesses 301 in the stack of nanosheets 210, thereby truncating the stack of nanosheets 210 into multiple stacks of nanosheets 210. The recesses 301 may also extend into the Si layer 103 of substrate 100 to create openings. By the nature of etch process, the recesses 301 and the openings in the Si layer 103 may have slanted sidewalls leading to a narrowed width at bottoms of the openings. The narrowed width at the bottoms of the openings would normally cause pinch-off of a liner in the openings when the liner is used to form inner spacers. However, because of thinner or smaller thicknesses of the sacrificial layers 212, a thinner liner may be used here which helps prevent pinch-off happening in the openings, as being described below in more details.

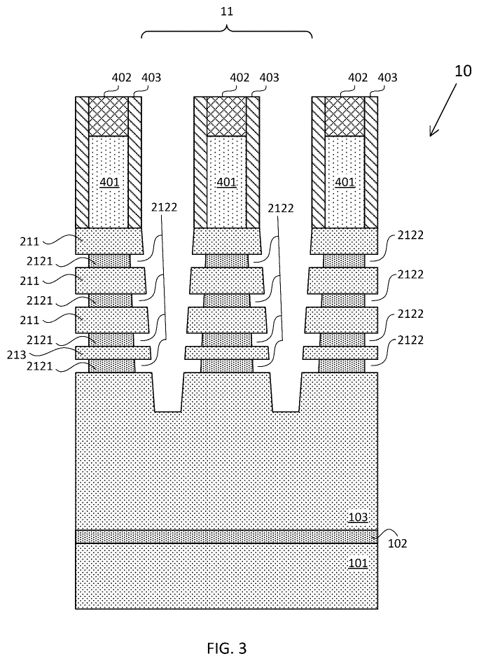

FIG. 3 is a demonstrative illustration of cross-sectional view of a semiconductor structure 10 in a step of manufacturing thereof, following the step illustrated in FIG. 2, according to one embodiment of present invention. More particularly, embodiments of present invention provide performing an indentation process of the set of sacrificial layers 212, from exposed sidewalls thereof, in a selective etch process relative to the set of Si nanosheets 211. For example, the indentation process may strategically apply etch selectivity between the Si nanosheets 211 and the sacrificial layers 212 of SiGe to selectively remove portions of the sacrificial layers 212 at the ends thereof. The indentation process may therefore create a set of sacrificial sheets 2121 with a plurality of indents 2122 at ends of the sacrificial sheets 2121.

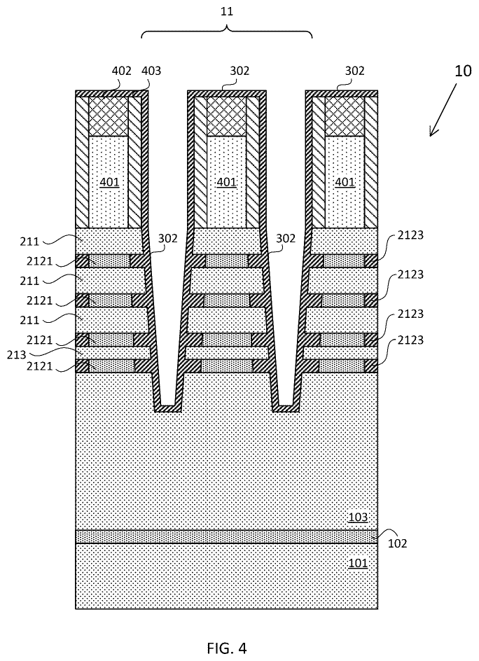

FIG. 4 is a demonstrative illustration of cross-sectional view of a semiconductor structure 10 in a step of manufacturing thereof, following the step illustrated in FIG. 3, according to one embodiment of present invention. More particularly, embodiments of present invention provide forming a conformal dielectric layer 302 that lines the recesses 301 in the S/D regions of the NS transistor 11. The conformal dielectric layer 302 may be formed through, for example, a deposition process such as a chemical-vapor-deposition (CVD) process, a physical-vapor-deposition (PVD) process, an atomic-layer-deposition (ALD) process, or other suitable deposition process. The conformal dielectric layer 302, which may be referred to as a conformal dielectric liner as well, may conformally cover sidewalls of the set of Si nanosheets 211, fill the indents 2122 at the ends of the sacrificial sheets 2121, and cover the openings in the Si layer 103 formed by the recesses 301.

The conformal dielectric layer 302 may be formed to have a thickness that is approximately equal to or larger than half of the thickness of the sacrificial sheets 2121 such that the conformal dielectric layer 302 may pinch off and fully fill the indents 2122 to form inner spacers 2123. In the meantime, the conformal dielectric layer 302 is thin enough such that it does not pinch off inside the openings in the Si layer 103. In one embodiment, the conformal dielectric layer 302 may include or be made of SiN, SiOx, or other suitable dielectric materials such as, for example, silicon-carbide (SiC), silicoboron-carbonitride (SiBCN), silicon-oxycarbonitride (SiOCN), or silicon-oxycarbide (SiOC).

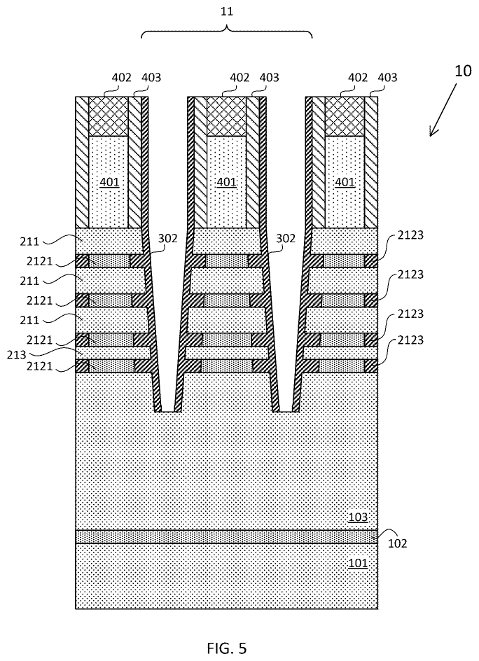

FIG. 5 is a demonstrative illustration of cross-sectional view of a semiconductor structure 10 in a step of manufacturing thereof, following the step illustrated in FIG. 4, according to one embodiment of present invention. More particularly, embodiments of present invention provide performing an anisotropic and/or directional etch process such as, for example, a reactive-ion-etch (RIE) process to remove horizontal portions of the conformal dielectric layer 302. The RIE process may remove a portion of the conformal dielectric layer 302 at the bottom of the openings such that the Si layer 103 underneath thereof may be exposed or re-exposed for further processing. The RIE process may also remove portions of the conformal dielectric layer 302 that cover the capping layer 402 and tops of the sidewall spacers 403 of the sacrificial gate structures 400.

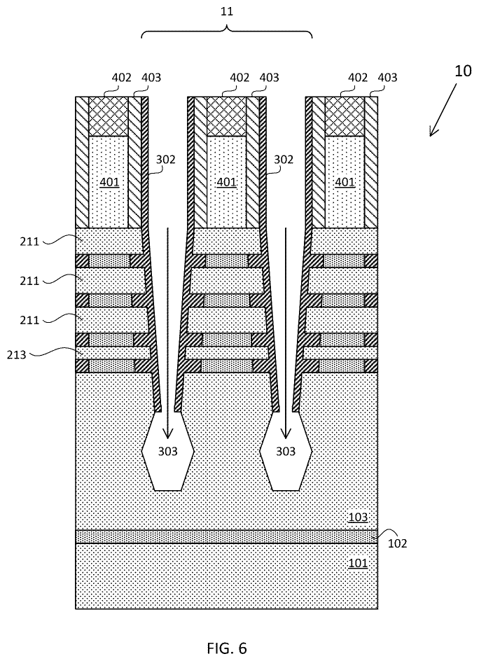

FIG. 6 is a demonstrative illustration of cross-sectional view of a semiconductor structure 10 in a step of manufacturing thereof, following the step illustrated in FIG. 5, according to one embodiment of present invention. More particularly, embodiments of present invention provide selectively etching the Si layer 103 exposed at the recesses 301 to create cavities 303 in the Si layer 103. The cavities 303 created through the etch process, such as through a selective RIE process, may be in diamond shape and may be later filled with other materials such as epitaxial SiGe to form placeholders. The etch process may leave the conformal dielectric layer 302 substantially unetched, which protects the Si nanosheets 211 that may be used later to form channel regions of the NS transistor 11.

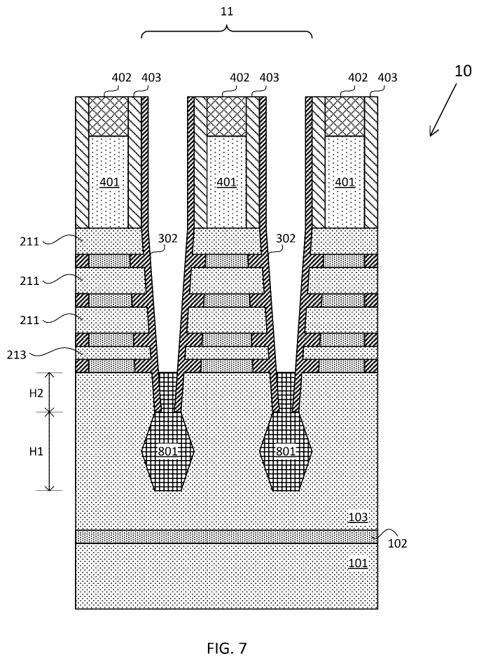

FIG. 7 is a demonstrative illustration of cross-sectional view of a semiconductor structure 10 in a step of manufacturing thereof, following the step illustrated in FIG. 6, according to one embodiment of present invention. More particularly, embodiments of present invention provide forming placeholders 801 in the cavities 303 and the openings above the cavities 303 in the Si layer 103 through an epitaxial growing process. For example, SiGe may be epitaxially grown from the Si material of the Si layer 103 at sidewalls of the cavities 303. The epitaxial SiGe may continue to grow in the openings above the cavities 303 that are surrounded by the conformal dielectric layer 302. The placeholders 801 may be formed to have a top surface that is around a top surface of the Si layer 103. For example, the top surface of the placeholders 801 may be grown initially to be at a level above the top surface of the Si layer 103 and subsequently be trimmed down, through an etch-back process, to be at approximately a same level as the top surface of the Si layer 103 of the semiconductor substrate 100.

As is illustrated in FIG. 7, the placeholders 801 may have a first portion and a second portion above the first portion. The first portion of the placeholders 801 may have a height H1 and have a diamond shape with multi-facets; and the second portion may have a height H2 and have an inverted trapezoidal shape with a wider base at top and a narrower base at bottom. The second portion of the placeholders 801 may be surrounded by the conformal dielectric layer 302, known as a dielectric liner. The placeholders 801 and the conformal dielectric layer 302 may be materially different.

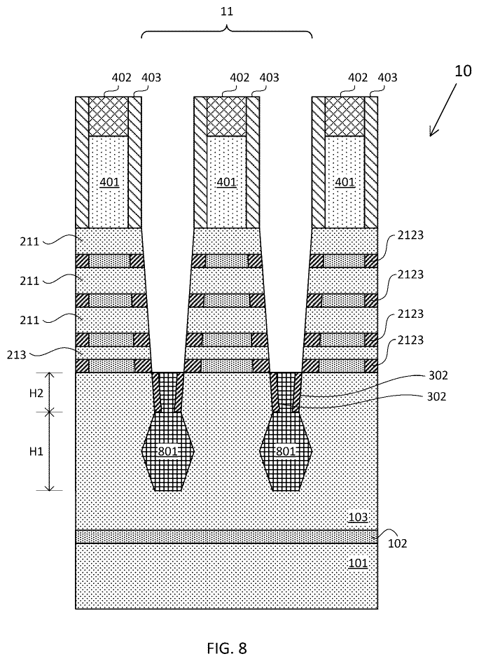

FIG. 8 is a demonstrative illustration of cross-sectional view of a semiconductor structure 10 in a step of manufacturing thereof, following the step illustrated in FIG. 7, according to one embodiment of present invention. More particularly, embodiments of present invention provide removing the conformal dielectric layer 302 at the ends of the Si nanosheets 211 as well as removing portions of the conformal dielectric layer 302 outside the indents 2122. The removal may be made through, for example, a wet etch process using hot phosphorus and may expose the end surfaces of the Si nanosheets 211 and leave pinched-off portions of the conformal dielectric layer 302 remaining at the ends of the sacrificial sheets 2121 thereby forming inner spacers 2123. The etch process may also remove the conformal dielectric layer 302 at the sidewall spacers 403 of the sacrificial gate structures 400.

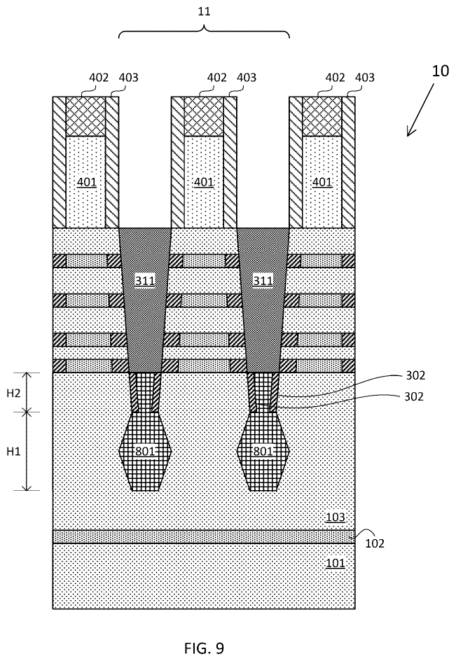

FIG. 9 is a demonstrative illustration of cross-sectional view of a semiconductor structure 10 in a step of manufacturing thereof, following the step illustrated in FIG. 8, according to one embodiment of present invention. More particularly, embodiments of present invention provide forming source/drain (S/D) regions 311 of the NS transistor 11 by epitaxially growing P+ Epi SiGe:B or N+ Epi Si:P from exposed end surfaces of the Si nanosheets 211, depending on the type of NS transistor 11 to be formed. Following the shape of the recesses 301, the S/D regions 311 of the NS transistor 11 may have slanted sidewalls and have a wider width at top and narrower width at bottom.

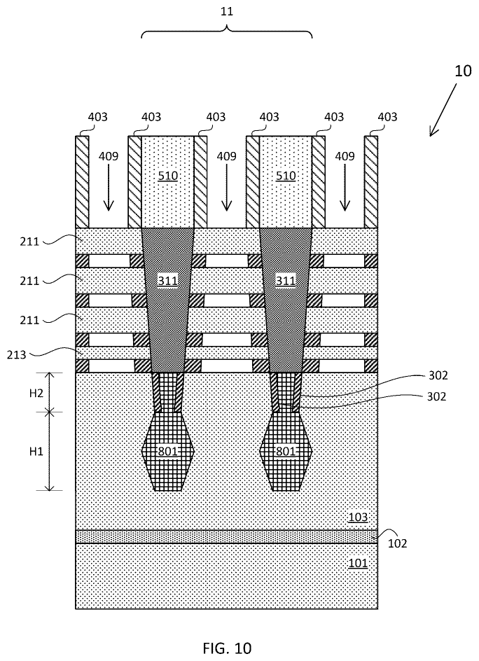

FIG. 10 is a demonstrative illustration of cross-sectional view of a semiconductor structure 10 in a step of manufacturing thereof, following the step illustrated in FIG. 9, according to one embodiment of present invention. More particularly, embodiments of present invention provide performing a replacement-metal-gate (RMG) process to form a metal gate of the NS transistor 11. In doing so, embodiments of present invention provide first covering the S/D regions 311 with a dielectric material thereby forming a dielectric layer 510 on top of the S/D regions 311. Next, the capping layer 402 of the sacrificial gate structures 400 may be removed, for example through a chemical-mechanical-polishing (CMP) process or a RIE process, to expose the sacrificial gates 401, and remove the exposed sacrificial gates 401 in a selectively etch process to create openings 409. After removing the sacrificial gates 401, embodiments of present invention provide removing, through the openings 409 in a selective etch process, the set of sacrificial sheets 2121 to expose a central portion of the set of Si nanosheets 211 and the Si nanosheet 213, while end portions of the set of Si nanosheets 211 and the Si nanosheet 213 may be covered, surrounded, or wrapped around by the sidewall spacers 403 and/or the inner spacers 2123.

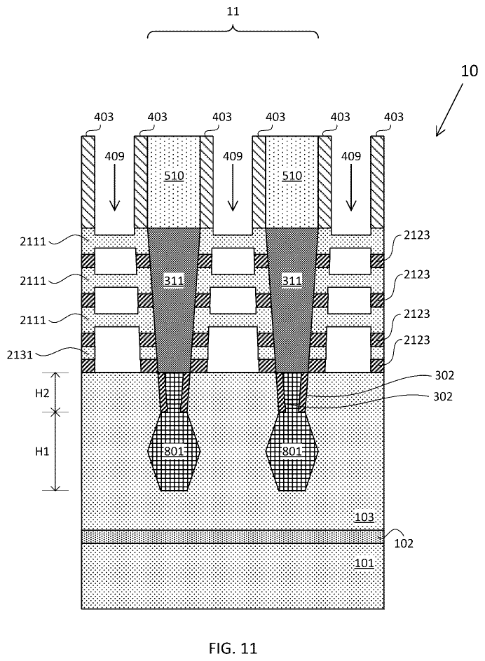

FIG. 11 is a demonstrative illustration of cross-sectional view of a semiconductor structure 10 in a step of manufacturing thereof, following the step illustrated in FIG. 10, according to one embodiment of present invention. More particularly, embodiments of present invention provide trimming the exposed central portions of the set of Si nanosheets 211 to increase the space between the set of Si nanosheets 211. For example, in one embodiment, a thickness of the central portions may be trimmed or thinned down to be about 50% to 70% of a thickness of the end portions of the Si nanosheets 211. The trimming therefore transforms the set of Si nanosheets 211 into a set of Si nanosheets 2111 with each of the Si nanosheets 2111 having a thinner central portion and thicker end portions. In other words, the central portion of each of the Si nanosheets 2111 has a thickness that is less than a thickness of the end portions of each of the Si nanosheets 2111.

In the meantime, the bottom-most Si nanosheet 213 has a thickness that is thinner than the thicknesses of the set of Si nanosheets 211. During the trimming or thinning process, the central portion of the bottom-most Si nanosheet 213 may be completely etched or trimmed away, leaving only end portions 2131 being surrounded by the inner spacers 2123. The complete removal of the central portion of the bottom-most Si nanosheet 213 helps increase the space or distance between the set of Si nanosheets 2111 and the Si layer 103 of the semiconductor substrate 100. Such increase in distance helps ensure that enough gate metal may be formed around the set of Si nanosheet 2111, during a later replacement-metal-gate (RMG) process, for proper control of a channel region of the NS transistor 11, thereby helps improving performance of the NS transistor 11.

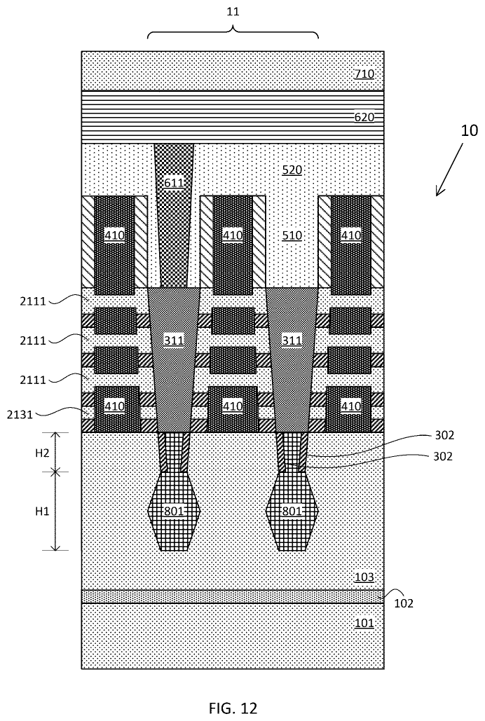

FIG. 12 is a demonstrative illustration of cross-sectional view of a semiconductor structure 10 in a step of manufacturing thereof, following the step illustrated in FIG. 11, according to one embodiment of present invention. More particularly, embodiments of present invention provide depositing a gate dielectric layer, through the openings 409, surrounding the central portions of the set of Si nanosheets 2111, depositing one or more work-function metal (WFM) layers on top of the gate dielectric layer, and depositing a conductive material on top of the one or more WFM layers thereby forming a set of metal gates 410. In other words, the central portions of the set of Si nanosheets 2111 may be covered, surrounded, or wrapped around by the set of metal gates 410. A CMP process may be applied to planarize a top surface of the set of metal gates 410 to be co-planar with the top surface of the dielectric layer 510. Next, additional dielectric materials such as a dielectric layer 520 may be formed through deposition on top of the set of metal gate 410 and on top of the dielectric layer 510; one or more frontside S/D contacts such as a S/D contact 611 may be formed to be in contact with the S/D region 311; and a back-end-of-line (BEOL) interconnect structure 620 may be formed on top of the dielectric layer 520. The BEOL interconnect structure 620 may provide signal routing, power supply, and other interconnect functions to the transistors such as the NS transistor 11 through the one or more frontside S/D contacts. After forming the BEOL interconnect structure 620, a handling wafer 710 may be attached, for example through a bonding process, to the BEOL interconnect structure 620 such as the semiconductor structure 10 may be flipped upside down for processing from the backside of the semiconductor substrate 100.

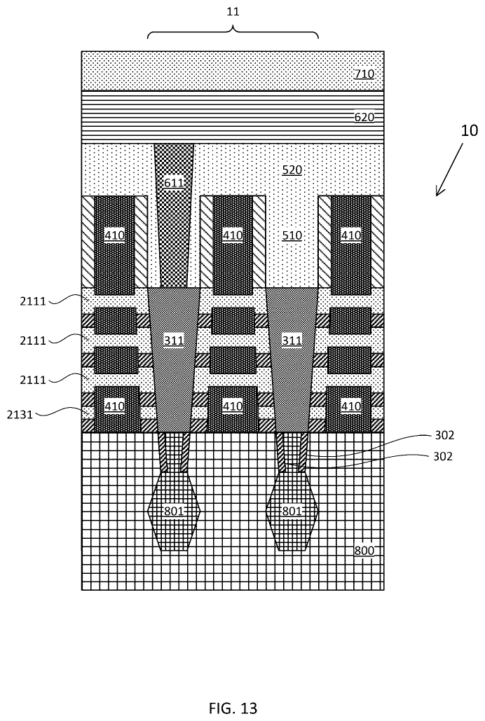

Hereinafter, although various processes may be applied from the backside of the semiconductor structure 10, for the ease of illustration, FIG. 13-15 will still be demonstratively illustrated upside-up and described according to that illustration.

FIG. 13 is a demonstrative illustration of cross-sectional view of a semiconductor structure 10 in a step of manufacturing thereof, following the step illustrated in FIG. 12, according to one embodiment of present invention. More particularly, embodiments of present invention provide removing the bulk Si substrate 101 through, for example, a CMP process, a grinding process, and/or other selective etch processes to stop at the dielectric layer 102; removing the dielectric layer 102 selectively to expose the Si layer 103; and removing the Si layer 103. The Si layer 103 may be selectively removed to expose the placeholders 801 which are made of a material, such as epitaxial SiGe, different from that of the Si layer 103. Next, a backside interlevel dielectric (BILD) layer 800 may be deposited, for example through a CVD process, a PVD process, and/or an ALD process, to cover the placeholders 801 such that the placeholders 801 may become embedded in the BILD layer 800.

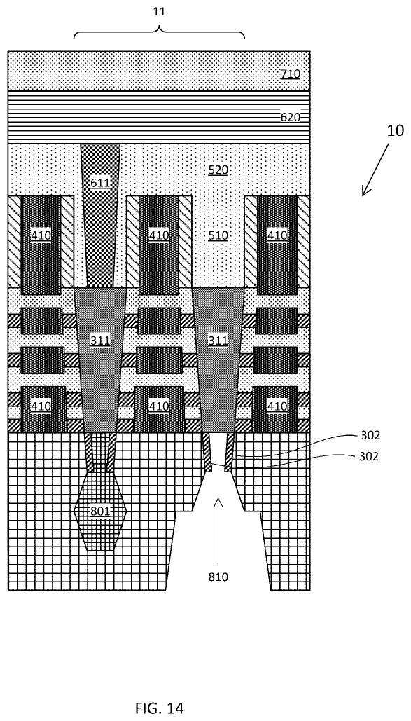

FIG. 14 is a demonstrative illustration of cross-sectional view of a semiconductor structure 10 in a step of manufacturing thereof, following the step illustrated in FIG. 13, according to one embodiment of present invention. More particularly, embodiments of present invention provide creating an opening 810 in the BILD layer 800, through a lithographic patterning process, to expose one of the placeholders 801 such as one of the placeholders 801 underneath a first S/D region 311 of the NS transistor 11. Next, the exposed placeholder 801 may be removed through a selective etch process. The selective etch process may remove the first portion of the placeholder 801 that is in the diamond shape and remove the second portion of the placeholder 801 that is surrounded by the conformal dielectric layer 302. The removal of the second portion of the placeholder 801 exposes a bottom surface of the S/D region 311.

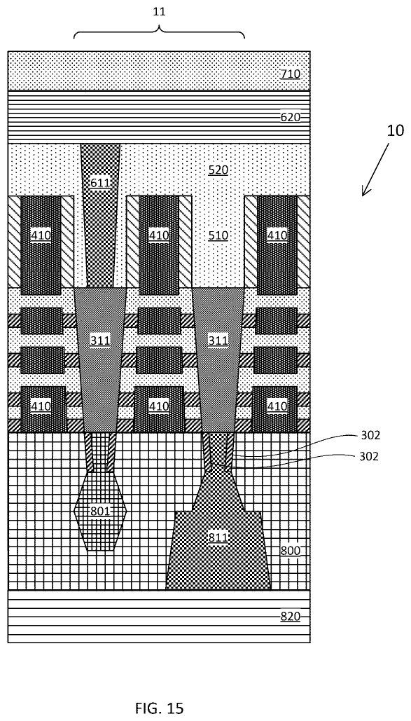

FIG. 15 is a demonstrative illustration of cross-sectional view of a semiconductor structure 10 in a step of manufacturing thereof, following the step illustrated in FIG. 14, according to one embodiment of present invention. More particularly, embodiments of present invention provide filling the opening 810 with a conductive material to form a backside contact 811 contacting the S/D region 311 of the NS transistor 11. As is illustrated in FIG. 15, a portion of the backside contact 811 may be surrounded by the conformal dielectric layer 302. A CMP process may be applied to planarize a bottom surface of the backside contact 811 to be co-planar with a bottom surface of the BILD layer 800. Subsequently, a backside BEOL structure 820 may be formed next to the BILD layer 800 to provide signal routing and/or power supply functions to the transistors such as the NS transistor 11.

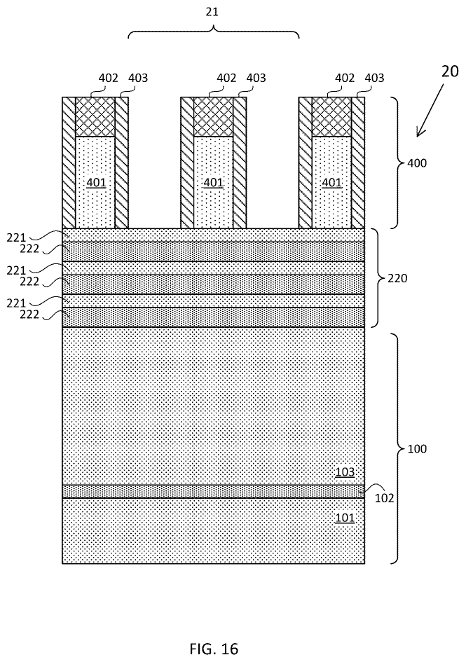

FIG. 16 to FIG. 31 are demonstrative illustrations of cross-sectional view of a semiconductor structure at various steps of manufacturing thereof according to another embodiment of present invention.

More particularly, FIG. 16 is a demonstrative illustration of cross-sectional view of a semiconductor structure 20 in a step of manufacturing thereof according to one embodiment of present invention. As a non-limiting example, the semiconductor structure 20 may include a transistor and more specifically may include a NS transistor 21. FIG. 16 illustrates a cross-sectional view of the NS transistor 21, at a step of manufacturing thereof, with a cross-section made along the length of gate of the NS transistor 21.

Embodiments of present invention provide receiving or providing a semiconductor substrate 100 and forming a stack of nanosheets 220 on top of the semiconductor substrate 100. The semiconductor substrate 100 may be a SOI substrate that includes a bulk Si substrate 101, a dielectric layer 102 on top of the bulk Si substrate 101, and a Si layer 103 on top of the dielectric layer 102. The stack of nanosheets 220 may include a set of Si nanosheets 221 stacked together, alternately, with a set of sacrificial layers 222. The set of sacrificial layers 222 may be a set of SiGe layers, which may have an etch selectivity that is different from the set of Si nanosheets 221.

In comparison with the set of Si nanosheets 211 and the set of sacrificial layers 212 in the stack of nanosheets 210 illustrated in FIG. 1, the set of Si nanosheets 221 is thinner than the set of Si nanosheets 211 while the set of sacrificial layers 222 is thicker than the set of sacrificial layers 212. In the meantime, the semiconductor structure 20 does not include any additional Si nanosheet, like the Si nanosheet 213 in the stack of nanosheets 210.

Embodiments of present invention provide forming a set of sacrificial gate structures 400 on top of the stack of nanosheets 220. Each of the sacrificial gate structures 400 may include a sacrificial gate 401, a capping layer 402 on top of the sacrificial gate 401, and sidewall spacers 403 at sidewalls of the sacrificial gate 401 and the capping layer 402. The sacrificial gate 401 may include, for example, Poly-Si in material, the capping layer 402 and sidewall spacers 403 may include dielectric material such as, for example, SiN, SiOx, or other suitable materials.

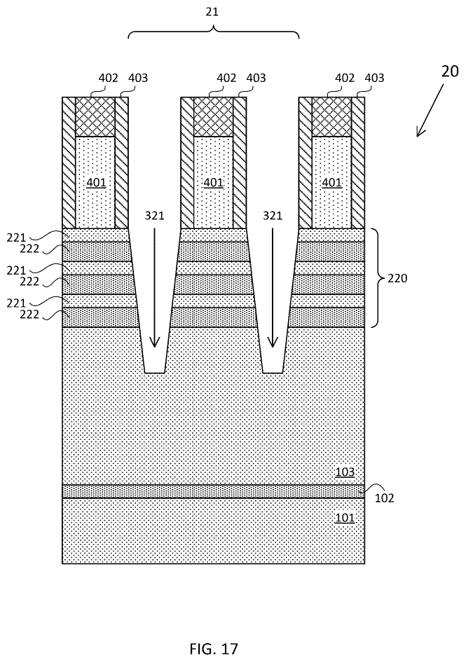

FIG. 17 is a demonstrative illustration of cross-sectional view of a semiconductor structure 20 in a step of manufacturing thereof, following the step illustrated in FIG. 16, according to one embodiment of present invention. More particularly, embodiments of present invention provide recessing the stack of nanosheets 220 in source/drain regions of the NS transistor 21, in a selective etch process using the sacrificial gate structures 400 as an etch mask. The recessing may create recesses 321 in the stack of nanosheets 220, thereby truncating the stack of nanosheets 220 into multiple stacks of nanosheets 220. The recesses 321 may also extend into the Si layer 103 of substrate 100 to create openings. By the nature of etch process, the recesses 321 and the openings in the Si layer 103 may have slanted sidewalls leading to a narrowed width at bottoms of the openings. The narrowed width at the bottoms may cause pinch-off of a liner when the liner is used to form inner spacers as being described below in more details.

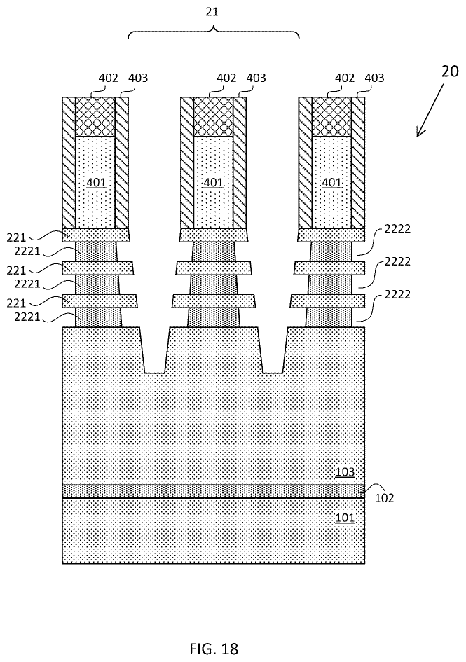

FIG. 18 is a demonstrative illustration of cross-sectional view of a semiconductor structure 20 in a step of manufacturing thereof, following the step illustrated in FIG. 17, according to one embodiment of present invention. More particularly, embodiments of present invention provide performing an indentation process by recessing the set of sacrificial layers 222, from exposed sidewalls thereof, in a selective etch process relative to the set of Si nanosheets 221. For example, the indentation process may strategically apply etch selectivity between the Si nanosheets 221 and the sacrificial layers 222 of SiGe to selectively remove portions of the sacrificial layers 222 at the ends thereof. The indentation process may thus create a set of sacrificial sheets 2221 with a plurality of indents 2222 at ends of the sacrificial sheets 2221.

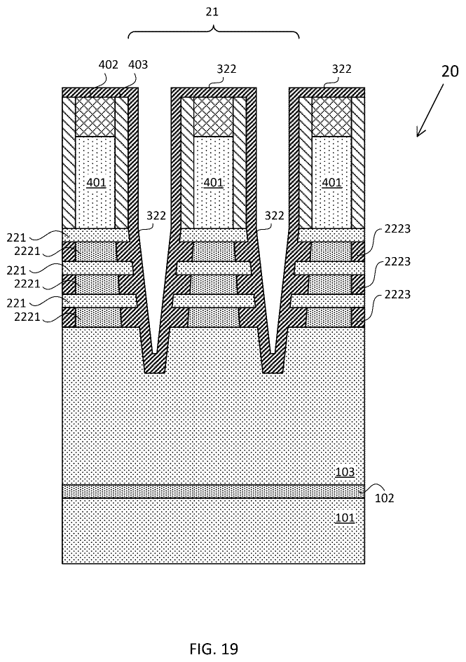

FIG. 19 is a demonstrative illustration of cross-sectional view of a semiconductor structure 20 in a step of manufacturing thereof, following the step illustrated in FIG. 18, according to one embodiment of present invention. More particularly, embodiments of present invention provide forming a conformal dielectric layer 322 that lines the recesses 321 in the S/D regions of the NS transistor 21. The conformal dielectric layer 322 may be deposited through, for example, a CVD process, a PVD process, an ALD process, or other suitable deposition process. The conformal dielectric layer 322, which may be referred to as a dielectric liner as well, may conformally cover sidewalls of the set of Si nanosheets 221, fill the indents 2222 at the ends of the sacrificial sheets 2221, and cover the openings in the Si layer 103 formed by the recesses 321.

The conformal dielectric layer 322 may be formed to have a thickness that is approximately equal to, or larger than, half of a thickness of the sacrificial sheets 2221 such that the conformal dielectric layer 322 may pinch off and fully fill the indents 2222 to form inner spacers 2223. Unlike the conformal dielectric layer 302 illustrated in FIG. 4, because the sacrificial sheets 2221 is thicker than the sacrificial sheets 2121, the conformal dielectric layer 322 is thicker than the conformal dielectric layer 302. The conformal dielectric layer 322 may pinch off, at least partially, inside the openings in the Si layer 103. In one embodiment, the conformal dielectric layer 322 may include or be made of SiN, SiOx, or other suitable dielectric materials such as, for example, SiC, SiBCN, SiOCN, or SiOC.

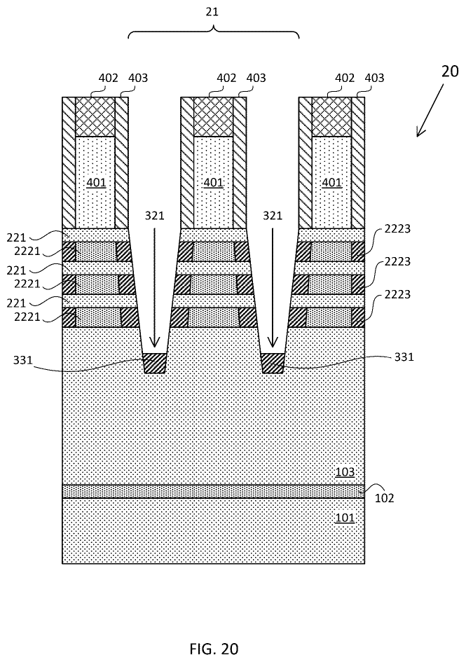

FIG. 20 is a demonstrative illustration of cross-sectional view of a semiconductor structure 10 in a step of manufacturing thereof, following the step illustrated in FIG. 19, according to one embodiment of present invention. More particularly, embodiments of present invention provide performing an isotropic etch process to remove portions of the conformal dielectric layer 322. The isotropic etch process may leave pinched-off portions of the conformal dielectric layer 322 inside the indents 2222 to form inner spacers 2223 and in a lower portion of the openings in the Si layer 103 to form one or more stubs 331 embedded in the Si layer 103.

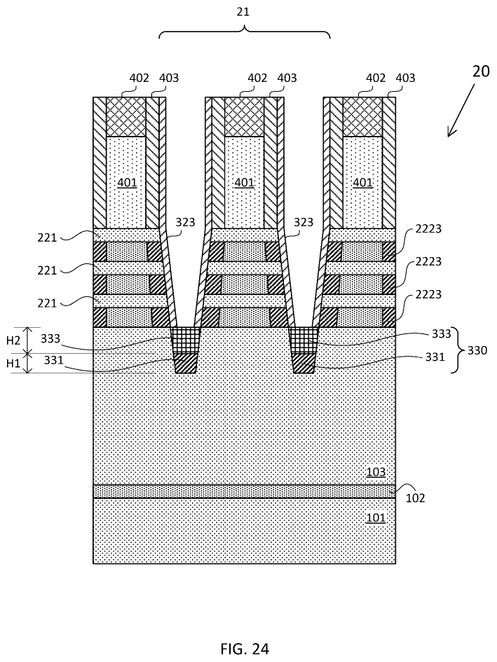

The stubs 331 may form a first portion of a placeholder 330 (see FIG. 24), as being described below in more details.

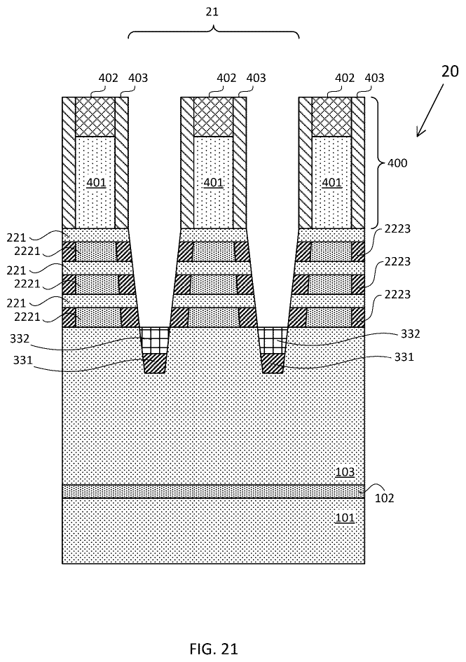

FIG. 21 is a demonstrative illustration of cross-sectional view of a semiconductor structure 20 in a step of manufacturing thereof, following the step illustrated in FIG. 20, according to one embodiment of present invention. More particularly, embodiments of present invention provide covering the stubs 331 with a strippable material to form a sacrificial layer 332 on top of the stubs 331. The strippable material may be, for example, a spin-on-glass (SOG) that may first be deposited into the recesses 321 to cover the stubs 331 and the sacrificial gate structures 400. A CMP process may be applied to planarize the strippable material to be coplanar with top surfaces of the sacrificial gate structures 400. The strippable material may then be recessed down to a level that is substantially aligned with a top surface of the Si layer 103.

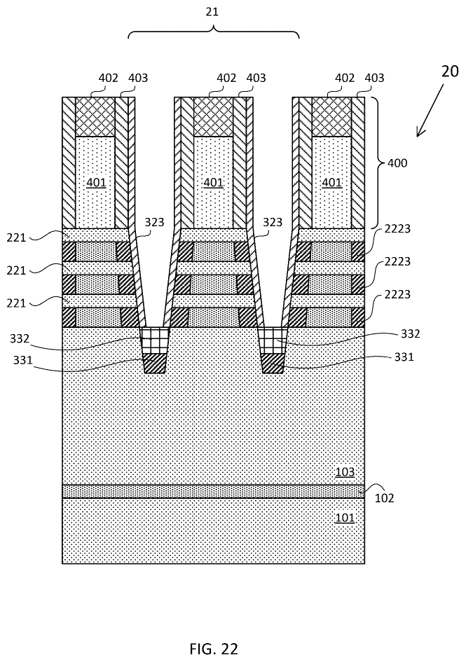

FIG. 22 is a demonstrative illustration of cross-sectional view of a semiconductor structure 20 in a step of manufacturing thereof, following the step illustrated in FIG. 21, according to one embodiment of present invention. More particularly, embodiments of present invention provide forming a conformal dielectric layer 323 lining sidewalls of the recesses 321. For example, a layer of dielectric material may be conformally deposited on top of the semiconductor structure 20 such that the layer of dielectric material covers top surfaces and sidewalls of the sacrificial gate structures 400, sidewalls of the stack of nanosheets 220, and top surfaces of the sacrificial layer 332. Next, a selective and/or directional etch process may be applied to remove horizontal portions of the layer of dielectric material resulting only vertical portion thereof to remain at sidewalls of the stack of nanosheets 220 and the sacrificial gate structures 400, thereby forming the conformal dielectric layer 323.

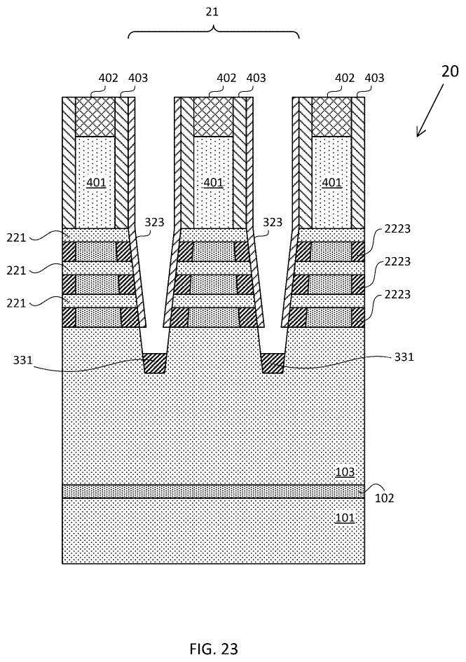

FIG. 23 is a demonstrative illustration of cross-sectional view of a semiconductor structure 20 in a step of manufacturing thereof, following the step illustrated in FIG. 22, according to one embodiment of present invention. More particularly, embodiments of present invention provide, with the conformal dielectric layer 323 covering sidewalls of the recesses 321, removing the sacrificial layer 332 in a selective etch process to expose or re-expose the stubs 331 embedded in the Si layer 103.

FIG. 24 is a demonstrative illustration of cross-sectional view of a semiconductor structure 20 in a step of manufacturing thereof, following the step illustrated in FIG. 23, according to one embodiment of present invention. More particularly, embodiments of present invention provide forming an epitaxial layer 333 on top of the stubs 331 replacing the sacrificial layer 332. The epitaxial layer 333 may be a layer of epitaxial SiGe and may be formed through an epitaxial growing process. The epitaxial layer 333 may become a second portion of the placeholder 330. As is demonstratively illustrated in FIG. 24, the first and the second portion of the placeholder 330 may have a first height H1 and a second H2 respectively, and a top surface of the second portion, that is, the epitaxial layer 333 may be formed or made to be coplanar with the top surface of the Si layer 103. The placeholder 330 may have an inverted trapezoidal shape with a wider base at top and a narrower base at bottom. During the epitaxial growing process, because the conformal dielectric layer 323 covers sidewalls of the stack of nanosheets 220, no epitaxial growth may happen in the rest of the recesses 321 such as at sidewalls or end surfaces of the set of Si nanosheets 221.

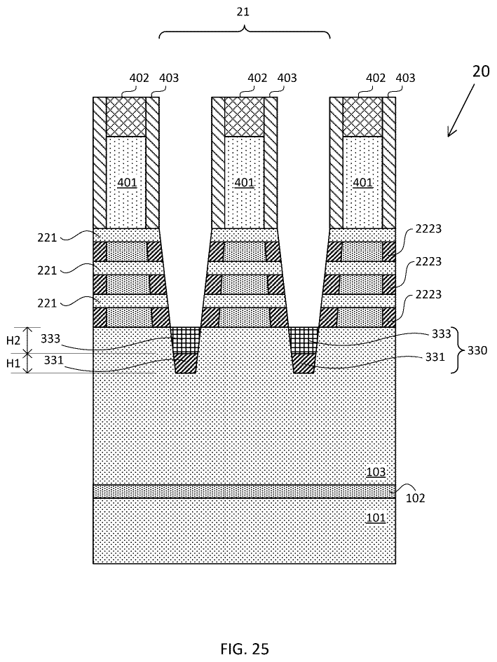

FIG. 25 is a demonstrative illustration of cross-sectional view of a semiconductor structure 20 in a step of manufacturing thereof, following the step illustrated in FIG. 24, according to one embodiment of present invention. More particularly, after forming the placeholders 330 in the Si layer 103, embodiments of present invention provide removing the conformal dielectric layer 323 to expose sidewalls or end surfaces of the stack of nanosheets 220, or more particularly to expose sidewalls or end surfaces of the set of Si nanosheets 221. The conformal dielectric layer 323 may be removed in a selective etch process such as, for example, a RIE process.

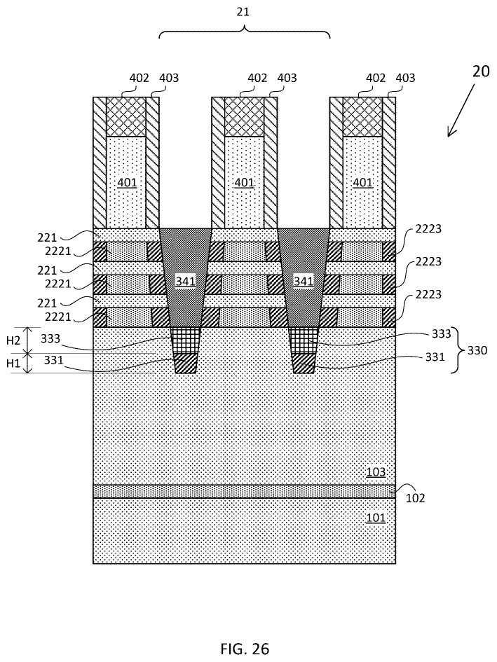

FIG. 26 is a demonstrative illustration of cross-sectional view of a semiconductor structure 20 in a step of manufacturing thereof, following the step illustrated in FIG. 25, according to one embodiment of present invention. More particularly, embodiments of present invention provide forming S/D regions 341 of the NS transistor 21 by epitaxially growing P+ Epi SiGe:B or N+ Epi Si:P from exposed end surfaces of the Si nanosheets 221, depending on the type of NS transistor 21 to be formed. Following the shape of the recesses 321, the S/D regions 341 of the NS transistor 21 may have slanted sidewalls and have a wider width at top and narrower width at bottom.

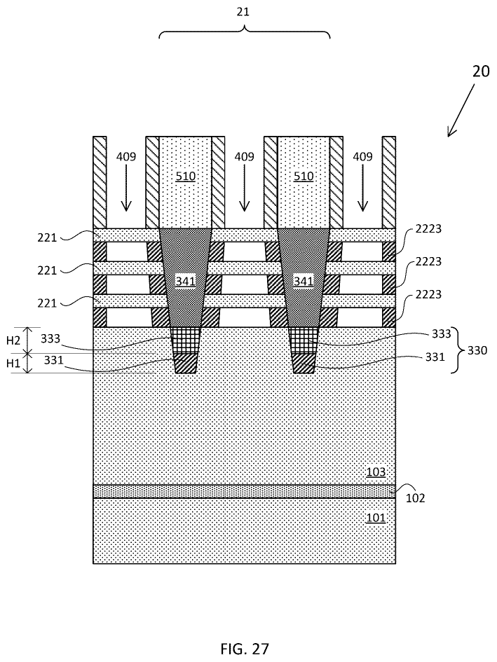

FIG. 27 is a demonstrative illustration of cross-sectional view of a semiconductor structure 20 in a step of manufacturing thereof, following the step illustrated in FIG. 26, according to one embodiment of present invention. More particularly, embodiments of present invention provide performing a RMG process to form a metal gate of the NS transistor 21. In doing so, embodiments of present invention provide first covering the S/D regions 341 with a dielectric material thereby forming a dielectric layer 510 on top of the S/D regions 341. Next, the capping layer 402 of the sacrificial gate structures 400 may be removed, for example through a CMP process, to expose the sacrificial gates 401, and remove the exposed sacrificial gates 401 in a selectively etch process to create openings 409. After removing the sacrificial gates 401, embodiments of present invention provide removing, through the openings 409 in a selective etch process, the set of sacrificial sheets 2221 to thereby expose a central portion of the set of Si nanosheets 221. In the meantime, end portions of the set of Si nanosheets 221 may remain covered, surrounded, or wrapped around by the sidewall spacers 403 and the inner spacers 2223.

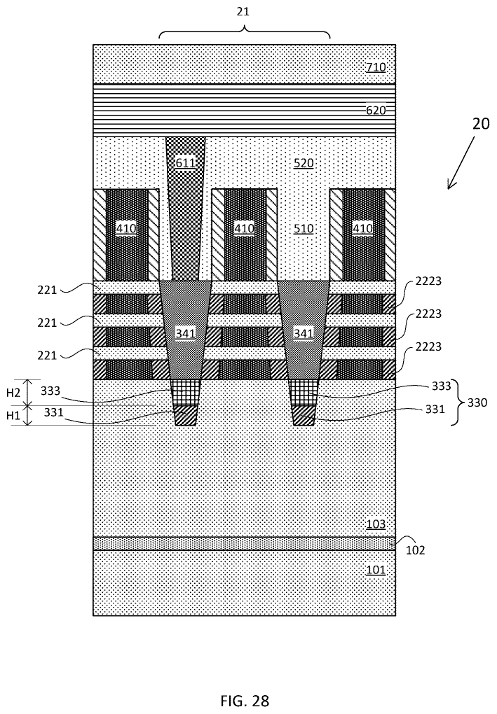

FIG. 28 is a demonstrative illustration of cross-sectional view of a semiconductor structure 20 in a step of manufacturing thereof, following the step illustrated in FIG. 27, according to one embodiment of present invention. More particularly, embodiments of present invention provide depositing a gate dielectric layer, through the openings 409, surrounding the central portions of the set of Si nanosheets 221, depositing one or more WFM layers on top of the gate dielectric layer, and depositing a conductive material on top of the one or more WFM layers thereby forming a set of metal gates 410. A CMP process may be applied to planarize a top surface of the set of metal gates 410 to be co-planar with the top surface of the dielectric layer 510. Next, additional dielectric materials such as a dielectric layer 520 may be formed through deposition on top of the set of metal gate 410 and on top of the dielectric layer 510; one or more frontside S/D contacts such as a frontside S/D contact 611 may be formed to be in contact with the S/D region 311; and a BEOL interconnect structure 620 may be formed on top of the dielectric layer 520. The BEOL interconnect structure 620 may provide signal routing, power supply, and other interconnect functions to the transistors such as the NS transistor 21 through the one or more frontside S/D contact.

After forming the BEOL interconnect structure 620, a handling wafer 710 may be attached, for example through a bonding process, to the BEOL interconnect structure 620 such that the semiconductor structure 20 may be flipped upside-down for processing from the backside of the semiconductor substrate 100.

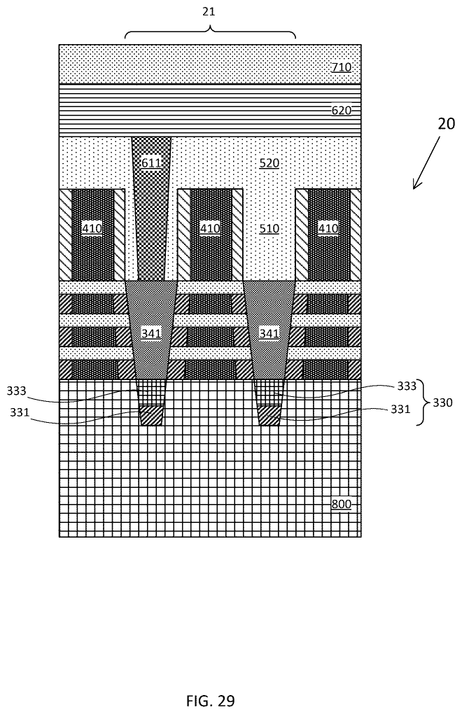

Hereinafter, although various processes may be applied from the backside of the semiconductor structure 20, for the ease of illustration, FIG. 29 - 31 will still be demonstratively illustrated upside-up and described according to that illustration.

FIG. 29 is a demonstrative illustration of cross-sectional view of a semiconductor structure 20 in a step of manufacturing thereof, following the step illustrated in FIG. 28, according to one embodiment of present invention. More particularly, embodiments of present invention provide removing the bulk Si substrate 101 through, for example, a CMP process, a grinding process, and/or other selective etch processes to stop at the dielectric layer 102; removing the dielectric layer 102 selectively to expose the Si layer 103; and removing the Si layer 103. The Si layer 103 may be selectively removed to expose the placeholders 330, which includes a first portion of the stubs 331 and a second portion of the epitaxial layers 333. The first and the second portion of the placeholders 330 are different in material and thus different in etch selectivity from that of the Si layer 103, which enables the selective removal of the Si layer 103. Next, a BILD layer 800 may be deposited, for example through a CVD process, a PVD process, and/or an ALD process, to cover the exposed placeholders 330 such that the placeholders 330 may become embedded in the BILD layer 800.

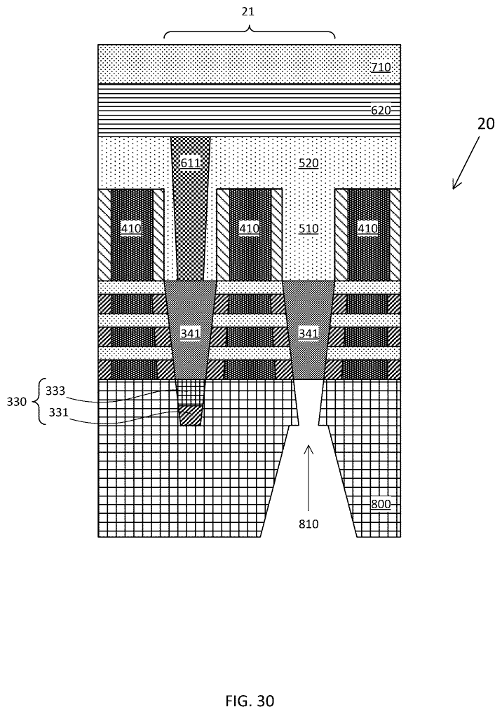

FIG. 30 is a demonstrative illustration of cross-sectional view of a semiconductor structure 20 in a step of manufacturing thereof, following the step illustrated in FIG. 29, according to one embodiment of present invention. More particularly, embodiments of present invention provide creating an opening 810 in the BILD layer 800, through a lithographic patterning process, to expose one of the placeholders 330 such as one of the placeholders 330 underneath a first S/D region 341. Next, the exposed placeholder 330 may be removed through a selective etch process. The selective etch process may remove both the first and the second portion of the placeholder 330 that are materially different from each other and different from the BILD layer 800. The removal of the placeholder 330 may expose a bottom surface of the S/D region 341.

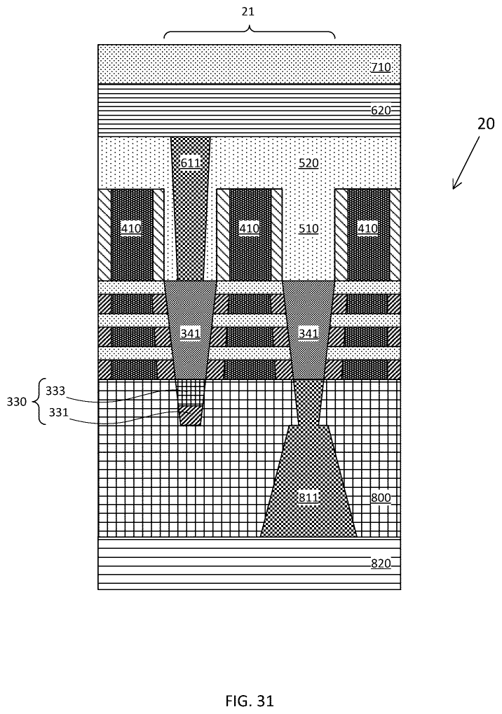

FIG. 31 is a demonstrative illustration of cross-sectional view of a semiconductor structure 20 in a step of manufacturing thereof, following the step illustrated in FIG. 30, according to one embodiment of present invention. More particularly, embodiments of present invention provide filling the opening 810 with a conductive material to form a backside contact 811 contacting the S/D region 341 of the NS transistor 21. A CMP process may be applied to planarize a bottom surface of the backside contact 811 to be co-planar with a bottom surface of the BILD layer 800. Subsequently, a backside BEOL structure 820 may be formed next to the BILD layer 800 to provide signal routing and/or power supply functions to the transistors such as the NS transistor 21.

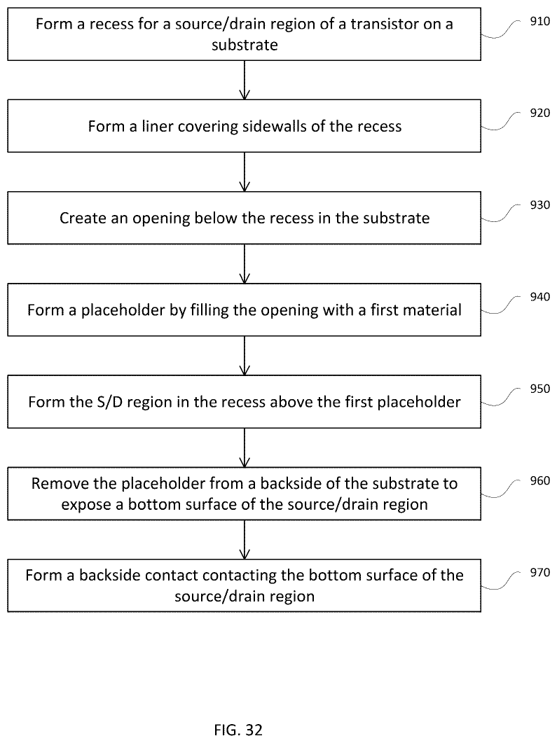

FIG. 32 is a demonstrative illustration of a flow-chart of a method of manufacturing a semiconductor structure according to embodiments of present invention. The method includes (910) forming a recess for a source/drain (S/D) region of a transistor on a substrate; (920) forming a liner covering sidewalls of the recess; (930) creating an opening below the recess in the substrate; (940) forming a placeholder by filling the opening with a first material; (950) forming the S/D region in the recess above the first placeholder; (960) removing the placeholder from a backside of the substrate to expose a bottom surface of the S/D region; and (970) forming a backside contact contacting the bottom surface of the S/D region.

Various examples may possibly be described by one or more of the following features in the following numbered clauses:

Clause 1: A semiconductor structure comprising a transistor having a first and a second source/drain (S/D) region; a backside contact in contact with a bottom surface of the first S/D region; and a placeholder underneath the second S/D region, wherein the placeholder is embedded in a backside interlevel-dielectric (BILD) layer and includes a first and a second material that are different from each other and different from a material of the BILD layer.

Clause 2: The semiconductor structure of clause 1, wherein the placeholder includes a first portion and a second portion over the first portion, the first portion being made of silicon-nitride and the second portion being made of epitaxial silicon-germanium, and wherein the BILD layer is made of silicon-oxide.

Clause 3: The semiconductor structure of clause 2, wherein the placeholder has an inverted trapezoidal shape with a wider base at top and a narrower base at bottom.

Clause 4: The semiconductor structure of clause 1, wherein the placeholder is made of epitaxial silicon-germanium and includes a first portion and a second portion over the first portion, the second portion being surrounded by a liner of silicon-nitride, and wherein the BILD layer is made of silicon-oxide.

Clause 5: The semiconductor structure of clause 4, wherein the first portion of the placeholder has a diamond shape and the second portion of the placeholder has an inverted trapezoidal shape with a wider base at top and a narrower base at bottom.

Clause 6: The semiconductor structure of clause 4, wherein the transistor is a nanosheet transistor having a plurality of nanosheets, and wherein a central portion of the plurality of nanosheets is surrounded by a metal gate of the transistor, the central portion of the plurality of nanosheets has a thickness that is less than a thickness of end portions of the plurality of nanosheets.

Clause 7: The semiconductor structure of clause 6, further comprising an additional nanosheet underneath the plurality of nanosheets, the additional nanosheet being truncated by the metal gate.

Clause 8: The semiconductor structure of clause 1, further comprising a frontside contact in contact with a top surface of the second S/D region.

Clause 9: A method of forming a semiconductor structure comprising forming a recess for a source/drain (S/D) region of a transistor on a substrate; forming a liner covering sidewalls of the recess; creating an opening below the recess in the substrate; forming a placeholder by filling the opening with a first material; forming the S/D region in the recess above the first placeholder; removing the placeholder from a backside of the substrate to expose a bottom surface of the S/D region; and forming a backside contact contacting the bottom surface of the S/D region.

Clause 10: The method of clause 9, wherein forming the placeholder further comprises filling a portion of the recess above the opening with the first material, wherein the portion of recess is surrounded by the liner, and the liner is made of a second material different from the first material.

Clause 11: The method of clause 9, further comprising trimming a set of nanosheets and wrapping around one or more trimmed nanosheets with a gate metal to form a metal gate of the transistor, wherein the set of nanosheets have a bottom-most nanosheet with a thickness that is thinner than rest of the set of nanosheets, and wherein trimming the set of nanosheets comprises truncating the bottom-most nanosheet.

Clause 12: The method of clause 9, wherein creating the opening comprises selectively removing a sacrificial layer in the substrate to expose an embedded stub of a second material, and wherein forming the placeholder comprises depositing the first material on top of the embedded stub to fill the opening.

Clause 13: The method of clause 12, further comprising creating a cavity in the substrate below the recess and filling the cavity with the second material to form the embedded stub at a lower portion of the cavity.

Clause 14: The method of clause 13, further comprising forming the sacrificial layer in the cavity above the embedded stub before forming the liner to cover sidewalls of the recess in the S/D region.

Clause 15: The method of clause 10, further comprising selectively removing the substrate and replacing with a layer of a third material, the third material being different from the first and the second material and surrounding the placeholder.

Clause 16: A semiconductor structure comprising a transistor having a first and a second source/drain (S/D) region; a backside contact in contact with a bottom surface of the first S/D region; and a placeholder underneath the second S/D region, wherein the placeholder is embedded in a backside interlevel-dielectric (BILD) layer and includes a first portion and a second portion of a first and a second material, the first and the second material are different from each other and different from a material of the BILD layer.

Clause 17: The semiconductor structure of clause 16, wherein the placeholder has an inverted trapezoidal shape with a wider base at top and a narrower base at bottom; the first portion of the placeholder is made of silicon-nitride and the second portion of the placeholder is made of epitaxial silicon-germanium and is formed on top of the first portion of the placeholder; and the BILD layer is made of silicon-oxide.

Clause 18: The semiconductor structure of clause 16, wherein the first and the second portion of the placeholder is made of epitaxial silicon-germanium and the second portion of the placeholder is surrounded by a liner of silicon-nitride and formed on top of the first portion of the placeholder.

Clause 19: The semiconductor structure of clause 18, wherein the first portion of the placeholder has a diamond shape, and the second portion of the placeholder has an inverted trapezoidal shape with a wider base at top and a narrower base at bottom.

Clause 20: The semiconductor structure of clause 19, wherein the transistor is a nanosheet transistor having a set of nanosheets, and wherein a central portion of each of the set of nanosheets has a thickness that is less than a thickness of end portions of the each of the set of nanosheets.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a transistor having a first and a second source/drain (S/D) region;
a backside contact in contact with a bottom surface of the first S/D region; and
a placeholder underneath the second S/D region,
wherein the placeholder is embedded in a backside interlevel-dielectric (BILD) layer and includes a first and a second material that are different from each other and different from a material of the BILD layer.

2. The semiconductor structure of claim 1, wherein the placeholder includes a first portion and a second portion over the first portion, the first portion being made of silicon-nitride and the second portion being made of epitaxial silicon-germanium, and wherein the BILD layer is made of silicon-oxide.

3. The semiconductor structure of claim 2, wherein the placeholder has an inverted trapezoidal shape with a wider base at top and a narrower base at bottom.

4. The semiconductor structure of claim 1, wherein the placeholder is made of epitaxial silicon-germanium and includes a first portion and a second portion over the first portion, the second portion being surrounded by a liner of silicon-nitride, and wherein the BILD layer is made of silicon-oxide.

5. The semiconductor structure of claim 4, wherein the first portion of the placeholder has a diamond shape and the second portion of the placeholder has an inverted trapezoidal shape with a wider base at top and a narrower base at bottom.

6. The semiconductor structure of claim 4, wherein the transistor is a nanosheet transistor having a plurality of nanosheets, and wherein a central portion of the plurality of nanosheets is surrounded by a metal gate of the transistor, the central portion of the plurality of nanosheets has a thickness that is less than a thickness of end portions of the plurality of nanosheets.

7. The semiconductor structure of claim 6, further comprising an additional nanosheet underneath the plurality of nanosheets, the additional nanosheet being truncated by the metal gate.

8. The semiconductor structure of claim 1, further comprising a frontside contact in contact with a top surface of the second S/D region.

9. A method of forming a semiconductor structure comprising:
forming a recess for a source/drain (S/D) region of a transistor on a substrate;
forming a liner covering sidewalls of the recess;
creating an opening below the recess in the substrate;
forming a placeholder by filling the opening with a first material;
forming the S/D region in the recess above the first placeholder;
removing the placeholder from a backside of the substrate to expose a bottom surface of the S/D region; and
forming a backside contact contacting the bottom surface of the S/D region.

10. The method of claim 9, wherein forming the placeholder further comprises filling a portion of the recess above the opening with the first material, wherein the portion of the recess is surrounded by the liner, and the liner is made of a second material different from the first material.

11. The method of claim 9, further comprising trimming a set of nanosheets and wrapping around one or more trimmed nanosheets with a gate metal to form a metal gate of the transistor, wherein the set of nanosheets have a bottom-most nanosheet with a thickness that is thinner than rest of the set of nanosheets, and wherein trimming the set of nanosheets comprises truncating the bottom-most nanosheet.

12. The method of claim 9, wherein creating the opening comprises selectively removing a sacrificial layer in the substrate to expose an embedded stub of a second material, and wherein forming the placeholder comprises depositing the first material on top of the embedded stub to fill the opening.

13. The method of claim 12, further comprising creating a cavity in the substrate below the recess and filling the cavity with the second material to form the embedded stub at a lower portion of the cavity.

14. The method of claim 13, further comprising forming the sacrificial layer in the cavity above the embedded stub before forming the liner to cover sidewalls of the recess in the S/D region.

15. The method of claim 10, further comprising selectively removing the substrate and replacing with a layer of a third material, the third material being different from the first and the second material and surrounding the placeholder.

16. A semiconductor structure comprising:
a transistor having a first and a second source/drain (S/D) region;
a backside contact in contact with a bottom surface of the first S/D region; and
a placeholder underneath the second S/D region,
wherein the placeholder is embedded in a backside interlevel-dielectric (BILD) layer and includes a first portion and a second portion of a first and a second material, the first and the second material are different from each other and different from a material of the BILD layer.

17. The semiconductor structure of claim 16, wherein the placeholder has an inverted trapezoidal shape with a wider base at top and a narrower base at bottom; the first portion of the placeholder is made of silicon-nitride and the second portion of the placeholder is made of epitaxial silicon-germanium and is formed on top of the first portion of the placeholder; and the BILD layer is made of silicon-oxide.

18. The semiconductor structure of claim 16, wherein the first and the second portion of the placeholder is made of epitaxial silicon-germanium and the second portion of the placeholder is surrounded by a liner of silicon-nitride and formed on top of the first portion of the placeholder.

19. The semiconductor structure of claim 18, wherein the first portion of the placeholder has a diamond shape, and the second portion of the placeholder has an inverted trapezoidal shape with a wider base at top and a narrower base at bottom.

20. The semiconductor structure of claim 19, wherein the transistor is a nanosheet transistor having a set of nanosheets, and wherein a central portion of each of the set of nanosheets has a thickness that is less than a thickness of end portions of the each of the set of nanosheets.
